(19) United States
(12) Patent Application Publication
(10) Pub. No.: US 2026/0055781 A1
(43) Pub. Date: Feb. 26, 2026

(54) ACOUSTIC METASURFACE WITH APERTURE SWITCHING MODULARITY

(71) Applicant: Dell Products L.P., Round Rock, TX (US)

(72) Inventors: Tejinder Singh, Manotick (CA); Navjot Kaur Khaira, Manotick (CA)

(21) Appl. No.: 18/811,219

(22) Filed: Aug. 21, 2024

(51) Int. Cl. F04D 29/66; H05K 7/20

(52) U.S. Cl. CPC F04D 29/665; H05K 7/20736

(57) ABSTRACT

The technology described herein is directed towards a metasurface arranged with unit cells for narrowband sound absorption, in which the unit cells are based on Helmholtz resonators that can have their resonant frequencies selected via interchangeable portions. A sound absorbing unit cell is designed and constructed in two parts based on a desired resonance frequency, such as a neck portion and air chamber portion. The portions are dimensioned such that when coupled together, Helmholtz resonators are formed that resonate at a desired resonance frequency and thereby inverse phase cancel corresponding narrowband frequencies of incoming sound waves. A portion with different dimensions can be interchanged to adjust the resonant frequencies to cancel acoustic waves of different frequencies corresponding to noise, which can change over time. The unit cells can be distributed as part of a metasurface, which can be positioned proximate to a noise source to phase cancel the noise.

### BACKGROUND

Acoustic absorbers are specialized materials or structures designed to mitigate the effects of sound reflections, echoes, and reverberations in various environments. These absorbers function by capturing sound waves and converting their energy into heat, effectively reducing the intensity of the sound waves and preventing them from bouncing off surfaces and causing unwanted sound reflections. They are typically engineered using porous materials with intricate structures that allow sound waves to penetrate deep into the material, where the acoustic energy is dissipated as thermal energy through friction and air resistance.

Existing acoustic absorbers come in various forms, including foam panels, fabric-wrapped panels, diffusers, bass traps, and more. One of the problems with existing acoustic absorbers is that they are not desirable in certain heat-sensitive environments. For example, servers generate a lot of heat and thus are designed with fans to cool dissipate the heat; however, fans can generate a lot of annoying noise. Using existing acoustic absorbers to absorb server noise reduces the noise, but can significantly reduce dissipation of the heat generated by servers, which can result in high heat levels that can reduce server performance and possibly cause a server to shut down to avoid damage from overheating.

### BRIEF DESCRIPTION OF THE DRAWINGS

The technology described herein is illustrated by way of example and not limited in the accompanying figures in which like reference numerals indicate similar elements and in which:

FIG. 1 is a conceptual representation of an example noise canceling metasurface showing a cavity sheet with interchangeably coupling aperture structures that facilitate different Helmholtz resonators based on the dimensions of the aperture structures, in accordance with various example embodiments and implementations of the subject disclosure.

FIG. 2A is a block diagram showing an example system for implementing a metasurface's neck port portion and chamber portion that can be coupled together for noise cancellation of acoustic waves, in accordance with various example embodiments and implementations of the subject disclosure.

FIG. 2B is a representation of an example metasurface deployed for noise cancellation, including resonators formed by coupling together a neck port portion and a chamber portion, in accordance with various example embodiments and implementations of the subject disclosure.

FIG. 3A is a two-dimensional side view representation of example two-part unit cells including one enlarged unit cell showing various dimensions, when the parts are combined, that determine the unit cell's resonance frequency, in accordance with various example embodiments and implementations of the subject disclosure.

FIG. 3B is a graphical representation of resulting absorption coefficient values of the unit-cell(s) of FIG. 3A over a range of frequencies, including a very high absorption coefficient value at the designed frequency 1310 Hz, in accordance with various example embodiments and implementations of the subject disclosure.

FIG. 4A is a side view representation of example Helmholtz resonator components, shown as separated into an aperture (neck port) portion and a cavity portion, in accordance with various example embodiments and implementations of the subject disclosure.

FIG. 4B is a two-dimensional side view representation of an example noise canceling Helmholtz resonator formed by coupling together the aperture portion and the cavity portion of FIG. 4A, in accordance with various example embodiments and implementations of the subject disclosure.

FIG. 5A is a side view representation of example Helmholtz resonator components, shown as separated into an aperture (neck port) portion (with different neck port dimensions relative to FIG. 4A) and a cavity portion, in accordance with various example embodiments and implementations of the subject disclosure.

FIG. 5B is a two-dimensional side view representation of an example noise canceling Helmholtz resonator formed by coupling together the aperture portion and the cavity portion of FIG. 5A, in accordance with various example embodiments and implementations of the subject disclosure.

FIG. 6A is a two-dimensional side view representation of an example noise canceling Helmholtz resonator formed by coupling together an aperture portion and a cavity portion, in accordance with various example embodiments and implementations of the subject disclosure.

FIG. 6B is a two-dimensional side view representation of an example noise canceling Helmholtz resonator formed by coupling together an aperture portion and a cavity portion, in which the cavity portion contains chambers with different dimensions relative to the chamber dimensions of FIG. 6A, in accordance with various example embodiments and implementations of the subject disclosure.

FIG. 7A is a side view representation of example Helmholtz resonator components, shown as a neck port and first partial cavity portion separated from a second partial cavity portion, in accordance with various example embodiments and implementations of the subject disclosure.

FIG. 7B is a two-dimensional side view representation of an example noise canceling Helmholtz resonator formed by coupling together the neck port and first partial cavity portion with the second partial cavity portion of FIG. 7A, in accordance with various example embodiments and implementations of the subject disclosure.

FIG. 8 is a three-dimensional representation of an example sound absorbing metasurface showing an enlarged view of an example unit cell with variable cavity dimensions, in accordance with various example embodiments and implementations of the subject disclosure.

FIG. 9 is a representation of an example portion of a sound absorbing metasurface showing an enlarged view of two of a metasurface's adjacent, variable cavity unit cells positioned to phase cancel a narrowband frequency within incoming acoustic waves from a server, in accordance with various example embodiments and implementations of the subject disclosure.

FIG. 10 is a representation of an example portion of a sound absorbing metasurface showing an enlarged view of two of a metasurface's adjacent, variable cavity unit cells positioned to phase cancel a narrowband frequency within incoming acoustic waves from a rack of servers, in accordance with various example embodiments and implementations of the subject disclosure.

FIG. 11 is a three-dimensional, perspective representation of an example sound absorbing metasurface composed of unit cells for wrapping around a rack of servers to reduce noise emanating from the servers, in accordance with various example embodiments and implementations of the subject disclosure.

FIG. 12 is a graphical representation showing example reflection coefficient data for frequency versus phase with respect to sound absorption, in accordance with various example embodiments and implementations of the subject disclosure.

FIG. 13 is a flow diagram showing example operations related to controlling a MEMS device to adjust a variable dimension of a Helmholtz resonator unit cell, to resonate the Helmholtz resonator unit cell to cancel acoustic wave noise, in accordance with various example embodiments and implementations of the subject disclosure.

### DETAILED DESCRIPTION

Various embodiments and implementations of the technology described herein are generally directed towards a sound absorbing device based on inverted phase cancellation, and more particularly towards Helmholtz resonators with selectable cavity dimensions based on coupling together interchangeable partial resonator portions. The technology described herein facilitates the design and implementation of such combined partial unit cells into metasurfaces that can be configured and positioned to efficiently absorb (or at least suppress to a large extent) and dissipate sound waves of a specific frequency. In the event that the frequency to absorb changes, the metasurface can be adjusted by changing one (or both) of the interchangeable unit cell resonator portions. Significantly, the use of metasurfaces as described herein do not increase the heat levels of computing devices substantially compared to existing technologies for sound absorption that do not facilitate ventilation/do not dissipate the heat very well. The specific frequency can be of any frequency/narrowband frequency range over a broad range of audible frequencies, or even subsonic (below 20 Hz)/supersonic frequencies (up to about 20,000 Hz).

Reference throughout this specification to “one embodiment,” “an embodiment,” “one implementation,” “an implementation,” etc. means that a particular feature, structure, or characteristic described in connection with the embodiment/implementation is included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, or characteristics may be combined in any suitable manner in one or more embodiments/implementations. It also should be noted that terms used herein, such as “optimize,” “optimization,” “optimal,” “optimally” and the like only represent objectives to move towards a more optimal state, rather than necessarily obtaining ideal results. For example, “optimal” placement of a subnet means selecting a more optimal subnet over another option, rather than necessarily achieving an optimal result. Similarly, “maximize” means moving towards a maximal state (e.g., up to some processing capacity limit), not necessarily achieving such a state.

Further, it is to be understood that the present disclosure will be described in terms of a given illustrative architecture; however, other architectures, structures, substrate materials and process features, and steps can be varied within the scope of the present disclosure.

It will also be understood that when an element such as a layer, region or substrate is referred to as being “on” or “over” another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

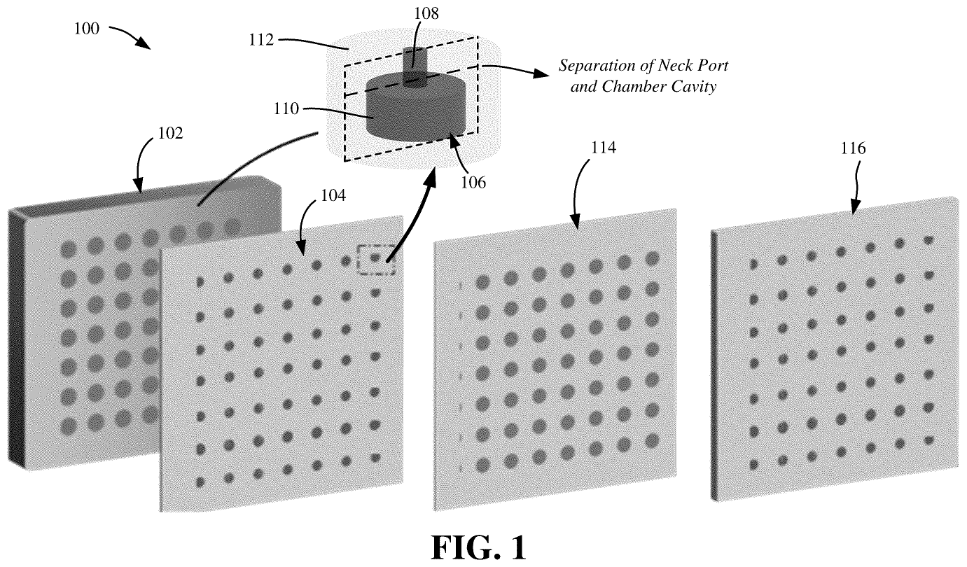

FIG. 1 shows the concept of a system 100 based on a multipart (two-portion) metasurface. In FIG. 1, a cavity sheet 102 (containing partial unit cells, namely the Helmholtz resonators' chambers) is configured to be coupled to one aperture sheet (neck port portion) of a group of interchangeable aperture sheets, each aperture sheet having different resonance characteristics. In this example the group includes a first sheet with a first neck port radius and length; the length corresponds to the thickness of the aperture sheet.

When the cavity sheet 102 is coupled to the aperture sheet 104, the openings align, whereby a unit cell/Helmholtz resonator is formed with a resonance frequency that depends on the cavity dimensions as described herein. In FIG. 1, one unit cell/Helmholtz resonator 106 is shown as enlarged; the Helmholtz resonator (darker-shaded portion) composed of the neck port 108 and chamber 110 is air, while the lighter-shaded surrounding portion 112 that is depicted in FIG. 1 is solid material, e.g., printed by a 3D printer. The dashed line shows the separation cut point between the neck portion (aperture sheet 104 containing the neck port 108) and the chamber portion (cavity sheet 102 containing the chamber 110).

Two other interchangeable aperture sheets 114 and 116 are shown. Relative to the aperture sheet 104, the aperture sheet 114 has larger neck port openings (hole radiuses), while the aperture sheet 114 has longer neck port lengths due to a thicker aperture sheet. Note that there can be any number of such aperture sheets in the group, and new ones can be 3D printed as needed; the cavity sheets can also be interchangeable as described herein. In general and as described herein, when one of the aperture sheets is selected and coupled to the cavity sheet 102, the different dimensions of the selected one of the interchangeable aperture sheets 104, 114 and 116 determine the resonance frequency of the unit cells.

By way of an example usage scenario, consider a two-piece metasurface of such unit cells configured to noise cancel the fan noise emanating from a server. The Helmholtz resonators' resonant frequency can be selected as described herein to significantly cancel the noise. Later, consider that the server fan changes its frequency as the server heats up/cools down, or that the server is replaced with a different server having a different fan noise frequency. Selecting a different aperture sheet operates to cancel the different frequency instead.

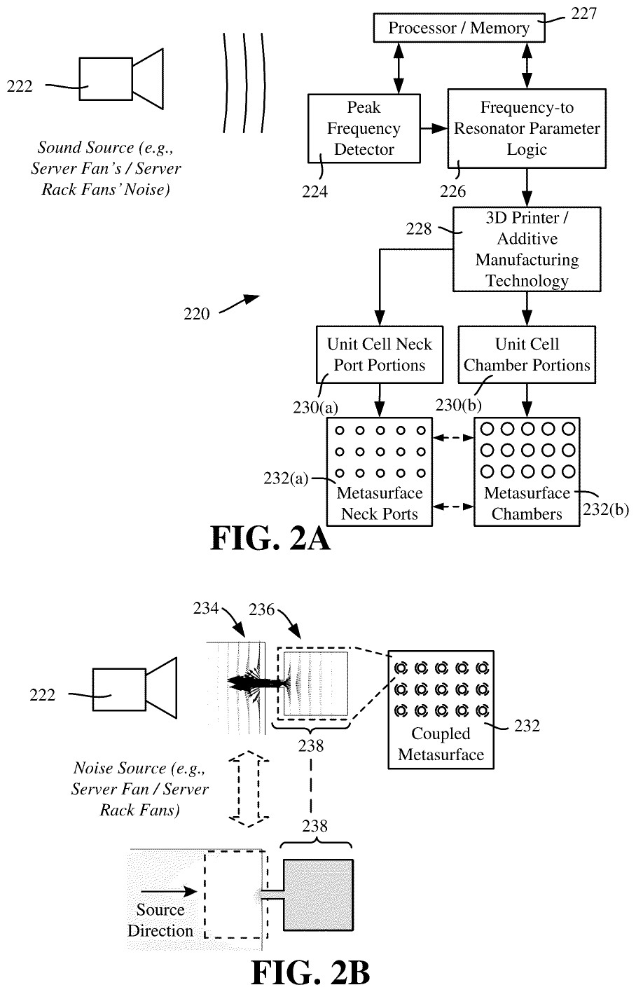

FIG. 2A shows a generalized block diagram of an example system 220 including a sound source 222 such as server fan/fans of a rack of servers that generate undesirable noise including at a frequency that is to be absorbed based on the technology described herein. A frequency measurement tool can be used as a peak frequency detector 224 or the like to determine which approximate narrowband frequency to cancel as described herein. As will be seen, the frequency itself is absorbed extremely efficiently by the technology described herein, with a narrow band of nearby frequencies also reduced to a lesser, but still desirable, extent.

Once the frequency to cancel is determined, frequency-to resonator parameter logic 226 can be used to determine the unit cell portions' parameters 230(a) and 230(b) that can inverse phase cancel that frequency. Based on these parameters 230(a) and 230(b), the separate parts of the unit cell, namely the neck port portions 232(a) and chamber portions 232(b), can be constructed with 3D printer/additive manufacturing technology 228. Once printed, the portions 232(a) and chamber portions 232(b) can be coupled together to form a full metasurface 232 as shown in FIG. 2B.

The unit cells are based on the principles of Helmholtz resonators, which are acoustic cavities with a small neck port or opening that are highly effective at absorbing specific frequencies via resonance. For example, the resonant frequency (f_{resonance}) of a classical Helmholtz resonator with respect to frequencies in the audible range is determined by:

$${f}_{resonance} = \frac{c}{2 π} \sqrt{\frac{S}{{L}_{p} V}}$$

where c is the speed of sound, S is the neck port cross-sectional area, Lₚ=L_{neck}+1.7r_{neck} (for a cylindrical neck port) and V is the unit cell's cavity chamber's volume.

The two-part unit cells, each represented as a small and slightly larger circle in FIGS. 2A and 2B, thus form a metasurface 232, which can then be positioned to cancel the noise source at the determined frequency. In one implementation, the metasurface 232 contains an array of the unit cell resonator units arranged in a two-dimensional pattern. For absorbing a server's fan noise, for example, the metasurface 232 can be positioned proximate to the server's location, or even wrapped around at least part of the server's housing. The same metasurface noise-cancellation concept can be extended to a rack of servers via appropriately-sized (e.g., larger) and/or more metasurfaces.

As generally represented in FIG. 2B, when incident sound waves (block 234) interact with the metasurface 232, the variable Helmholtz resonators within the array selectively absorb the corresponding frequencies via inverse phase cancellation (represented by vectors in blocks 234 and 236). As sound waves enter the resonators (e.g., the resonator 238) through the neck port, they create pressure fluctuations within the cavities. By engineering the geometrical parameters of the cavity/air chamber and neck port, and then coupling the appropriate sheets together as described herein, the resulting resonance frequency of the unit cell creates a π phase shift reflected wave with respect to the incident wave as shown in FIG. 2B, where the two sets of waves with opposite phase cancel, effectively absorbing the frequency. This is highlighted via the air velocity vector plot showing the direction of the reflected wave with π phase shift in the upper portion of FIG. 2B. In addition, these pressure fluctuations also cause the air inside the cavities to oscillate, effectively converting acoustic energy into kinetic energy. This kinetic energy is then dissipated as heat through viscous losses in the narrow neck of the resonators, however the heat dissipation is appreciably better relative to traditional sound absorbers and does not significantly affect thermal performance of a server.

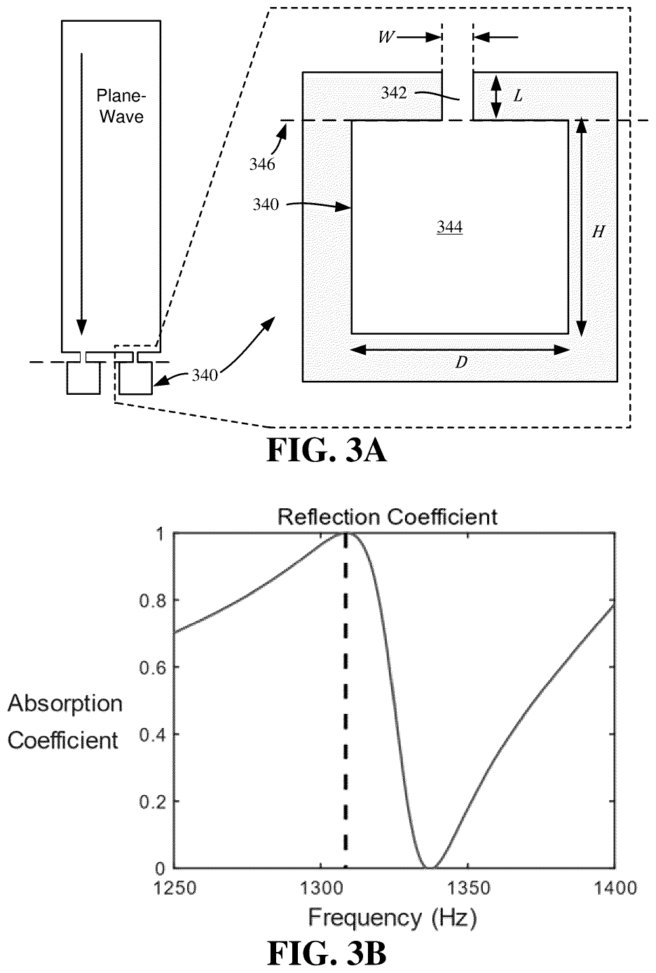

As generally represented in FIG. 3A, each unit cell 340 comprises a neck port 342 that exposes the air chamber 344 to the air/incoming sound waves and a cavity, with dimensions engineered to target a particular frequency or a narrowband range of frequencies of interest. The dimensions of the air chamber 344 and neck port 342 are designed based on generally desired narrow band of acoustic frequencies to cancel, allowing the unit cells of the metasurface 232 (FIG. 2B) to resonate when exposed to sound waves of those frequencies.

The neck port 342 and the chamber 344 are separately constructed and coupled together, as represented by the line 346. When coupled together, the air chamber 344 and neck port 342, which are hollow to contain air, are enclosed in their now-coupled supporting structures through which the neck port 342 extends to couple the chamber to the air propagating the sound wave.

FIG. 3A illustrates the unit cell's dimensions, which are “variable” during initial design before fabrication, and then once constructed and deployed, are selectively variable via changing one or both metasurface portions as described herein. The dimensions include the chamber height (H), and in the example of a cylindrical air chamber, the chamber's diameter (D) which is twice the radius, such that a cylindrical air chamber's volume is:

$$V = {( π \times \frac{1}{2} D )}^{2} \times H .$$

The neck port, which is also a cylindrical tube in this example, has an area of

$${( π \times \frac{1}{2} W )}^{2}$$

and a length of L. The combined unit cell is not limited to cylindrical air chambers or cylindrical necks, but can be of any suitable shape that facilitates resonating at the desired frequency in a manner that phase cancels the incoming sound wave of that frequency.

The result is highly efficient sound absorption at specific frequencies as shown in FIG. 3B, which in this example is around 1310 Hz, making this metasurface particularly useful for targeted noise reduction in environments where controlling specific frequencies is beneficial, such as in architectural acoustics, automotive design, and industrial settings. The dimensions are deep subwavelength values relative to the subwavelength of the incoming wave. For example, one metasurface implementation was designed to inverse phase cancel an incoming frequency 1310 Hz, with selected unit-cell dimensions of D=18 mm, H=16 mm, L=6 mm, W=3.2 mm. The resulting absorption coefficient of the designed unit-cell achieved near-perfect (greater than 98 percent absorption at the designed frequency 1310 Hz), as shown in FIG. 3B. As can be seen from this example, the structure is deeply sub-wavelength; the wavelength λ at 1310 Hz in air is 360 mm, which is controlled by unit-cell with thickness of 32 mm. As can be seen, the above-selected dimensions of D, H, L and W for 1310 hertz (λ=260 m) in air range from about λ/14 to λ/81 (or λ/13 if based on the thickness of 32 mm). Note that while the curve of FIG. 3B shows about seventy percent absorption effectiveness around 1250 Hz increasing to the peak absorption at the desired frequency 1310 Hz, the curve can be flattened more around the designed frequency to an extent, e.g., by slightly tweaking the dimensions of some of the unit cells.

The designed unit cell only needs air and its surrounding acoustic hard boundaries. This is different from other approaches using porous and fibrous materials and gradient index materials. At this scale the unit-cell acts almost like a point towards the wave, so this design is not straightforward. However, the materials and the compact design in mm-scale/deeply sub-wavelength facilitate fabricating the unit cell as a thin, light-weight, and cost effective absorber with 3D printing technology.

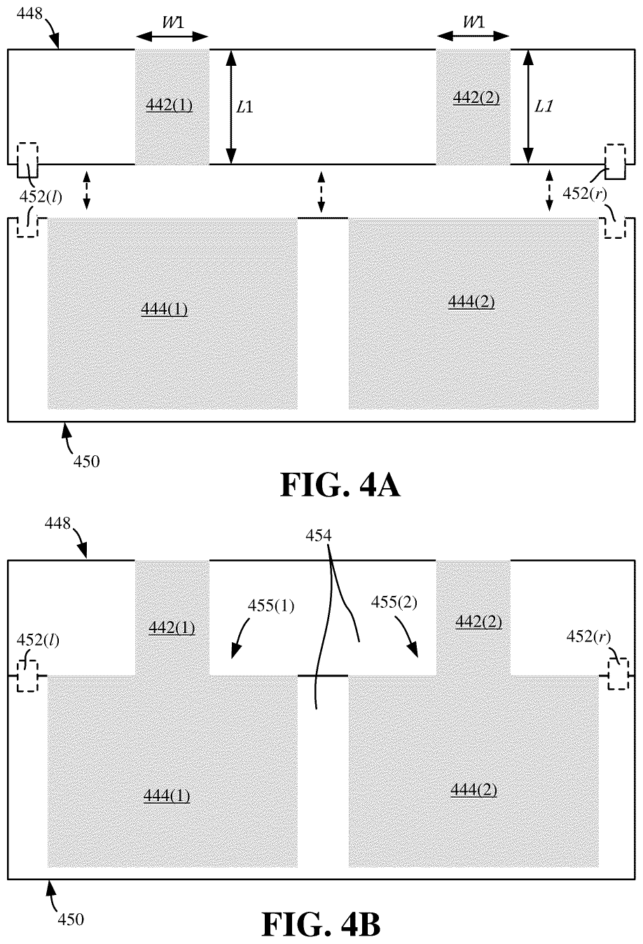

FIGS. 4A and 4B are two-dimensional side views showing the concept of a Helmholtz resonator being formed by coupling together different metasurface portions. In this example, two of the metasurface's neck ports 442(1) and 442(2) are depicted, along with their counterpart chambers 444(1) and 444(2), respectively. As shown in FIG. 4A, the neck portion 448 (e.g., aperture sheet) and chamber portion 450 (e.g., cavity sheet) are separately fabricated. In this example, left and right couplings 452(l) and 452(r), respectively, that facilitate proper alignment of the neck ports and chambers, and secure the portions 448 and 450 together, are depicted, although as is understood, more couplings are likely to be present in a full three-dimensional metasurface of many unit cells. Further, any type of coupling can be used, e.g., mechanical, magnetic, and so forth, and such couplings can be part of a frame that holds the two portions 448 and 450 together, rather than being constructed with or attached to the separate portions.

As can be seen in FIG. 4B, when the portions 448 and 450 are coupled together, a full metasurface 454 is formed, including the now formed Helmholtz resonators 455(1) and 455(2). Note that the neck port dimensions L1 and W1 are shown, for use in comparing with neck ports of different dimensions.

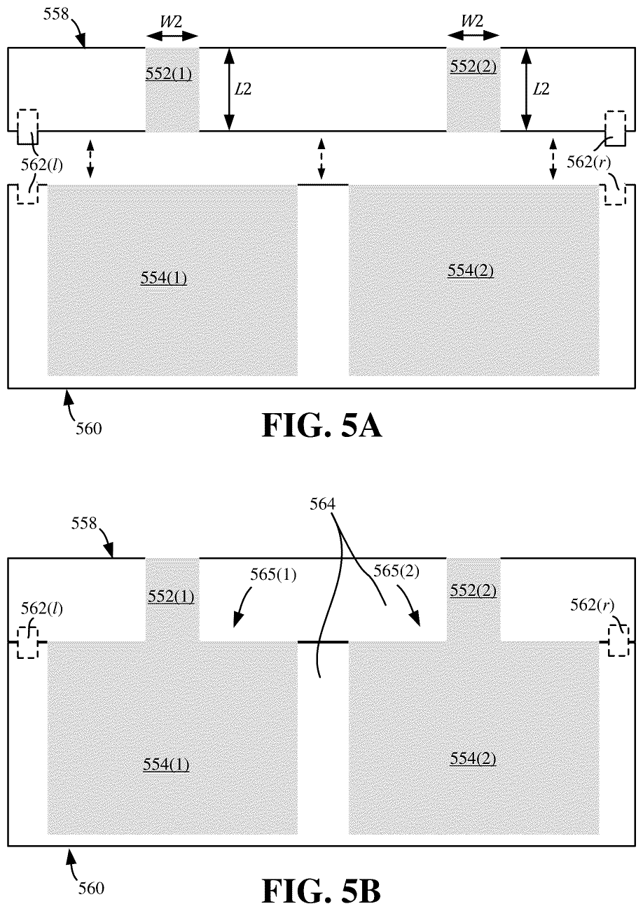

More particularly, FIGS. 5A and 5B are similar two-dimensional side views to those of FIGS. 4A and 4B, however the neck port dimensions are two-dimensional side views are L2 and W2. In this example, both L2≠L1 and W2≠W1, however only one of the dimensions needs to be different for the resonance frequencies of the unit cells to change.

In FIGS. 5A and 5B, two of the metasurface's neck ports 552(1) and 552(2) are depicted, along with their counterpart chambers 554(1) and 554(2), respectively. As shown in FIG. 4A, the neck portion 558 (e.g., aperture sheet) and chamber portion 560 (e.g., cavity sheet) are separately fabricated. In this example, left and right couplings 562(l) and 562(r), respectively, that facilitate proper alignment of the neck ports and chambers, and secure the portions 558 and 560 together, are similarly depicted. As can be seen in FIG. 5B, when the portions 558 and 560 are coupled together, a full metasurface 564 is formed, including the now formed Helmholtz resonators 565(1) and 565(2).

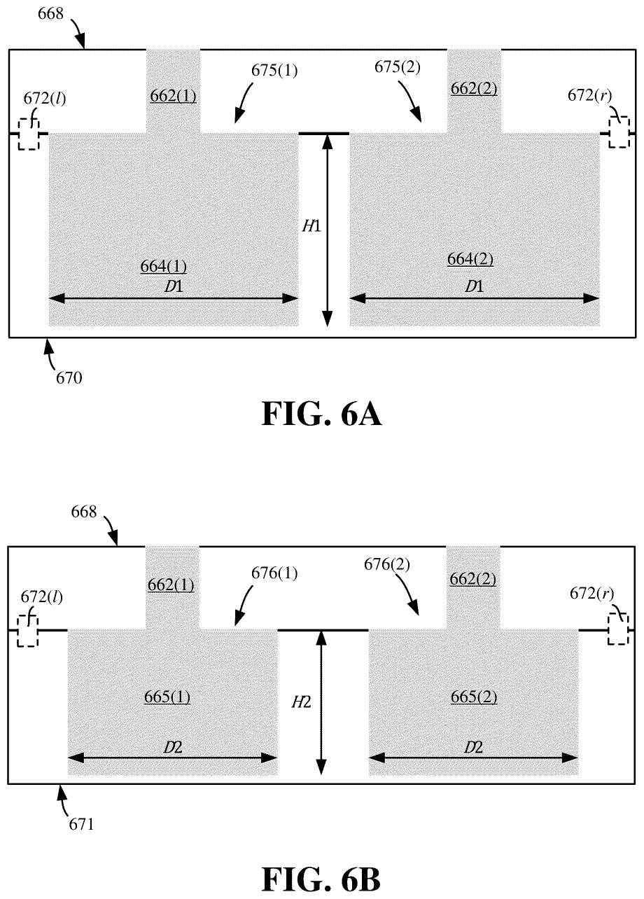

FIGS. 6A and 6B show the concept of different-sized chambers (e.g., 664(1) and 665(1)), forming different resonators (e.g., 675(1) and 676(1)) when the portions 668 and 670, or portions 668 and 671, are coupled together. As shown in FIGS. 6A and 6B, the chamber dimensions of the chamber portion 670 of FIG. 6B are H1 and D1, whereas the chamber dimensions of the chamber portion 671 are H2 and D2. In this example, both H2≠H1 and D2≠D1, however only one of the chamber's dimensions needs to be different for the resonance frequencies of the unit cells to change. The neck ports 662(1) and 662(2) are unchanged from FIG. 6A to FIG. 6B.

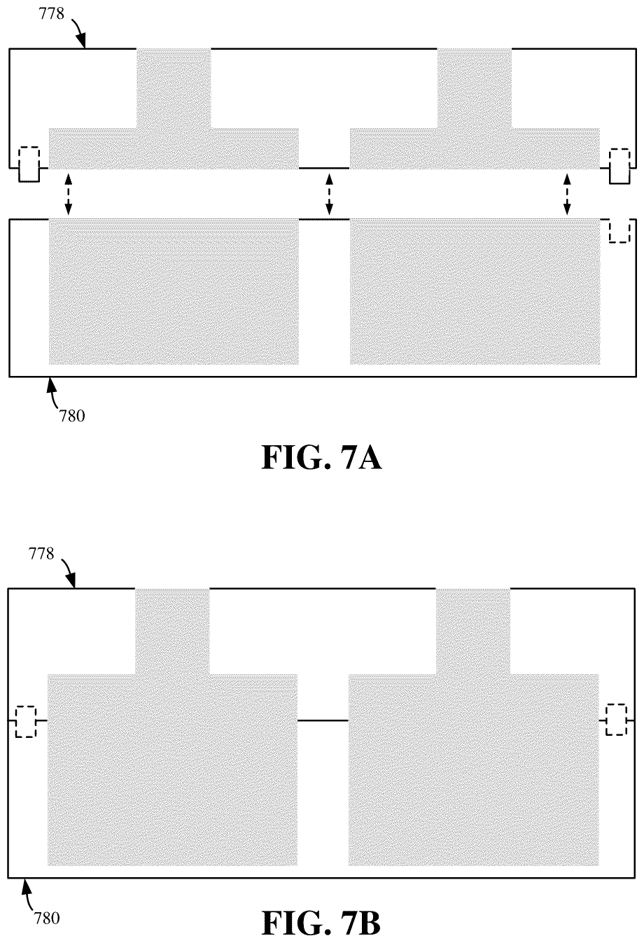

FIGS. 7A and 7B show another concept, namely that the two portions 778 and 780 need not be separated at the neck ports, but, for example, one portion can include the neck ports and part of the chamber, and the other portion can include the other part of the chamber. For example, consider a metasurface two-part system in which the chamber diameter does not change, such as with the cavity sheet 102 of FIG. 1. Instead of having different aperture sheets of different neck port dimensions, there can be aperture sheets of both different neck port dimensions and/or different partial chamber heights, providing more flexibility in terms of selecting the matching resonance frequency. Similarly, although not explicitly depicted, it is also feasible to have one portion include one part of the neck ports, and the other portion include the other part of the neck ports and the chambers. More than two portions can also be combined into a metasurface, e.g., a chamber portion, a neck port portion, and a neck port extension portion is one possible non-limiting combination.

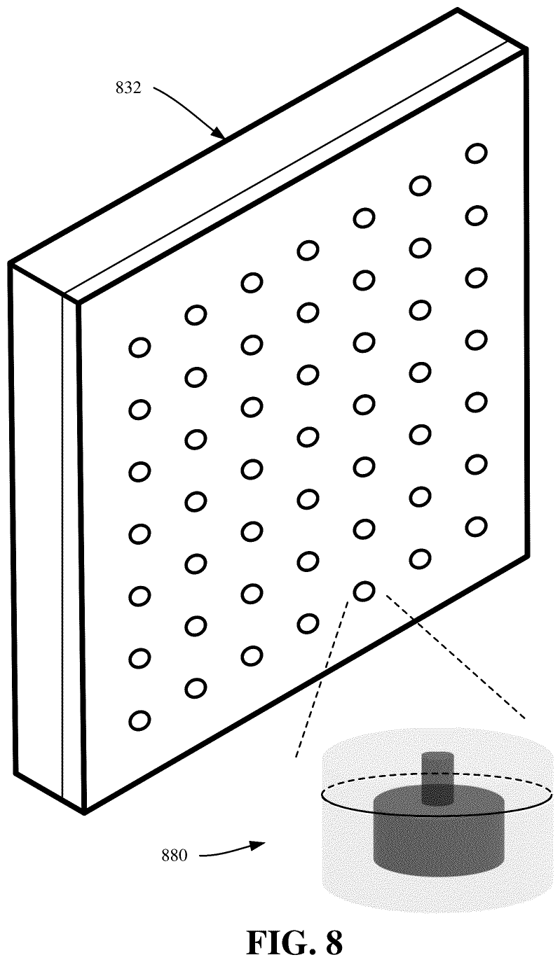

The sound absorbing unit cells can be fabricated using 3D printing technology with the features of material simplicity and deeply sub-wavelength compact design. An illustration of an example coupled, two-part metasurface 832 with an arrayed distribution of coupled two-part unit-cells (one of which labeled 880 is enlarged) is shown in FIG. 8.

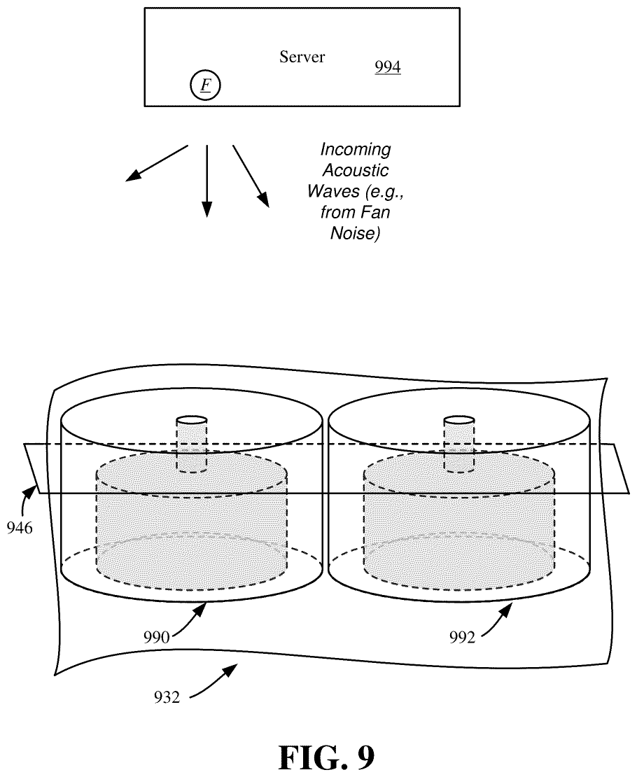

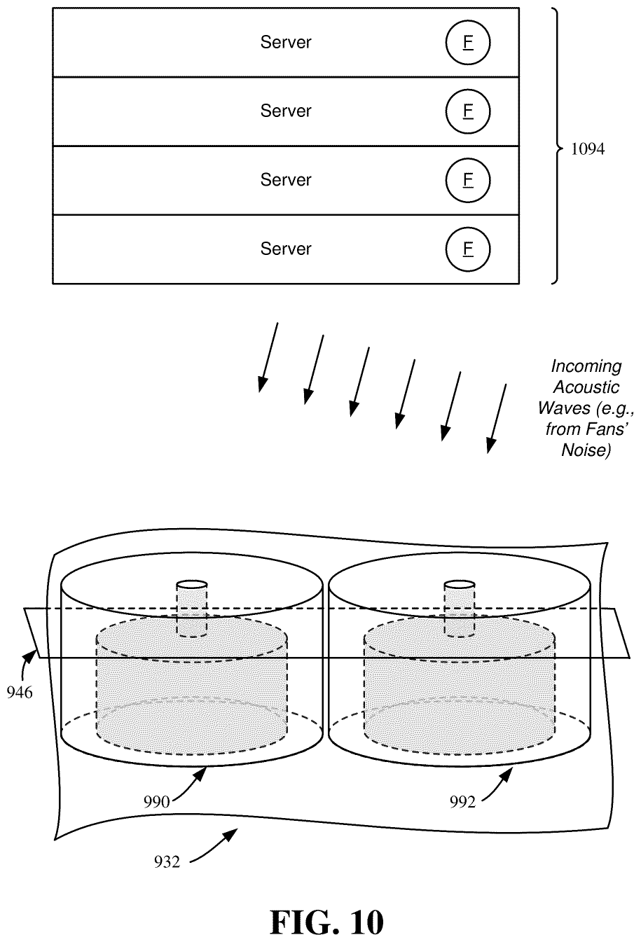

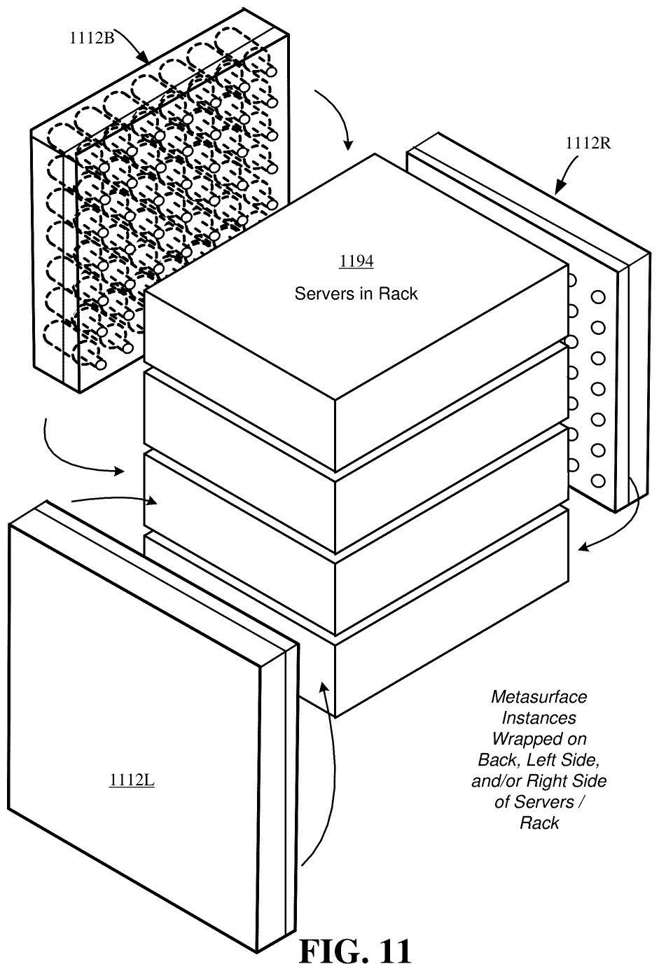

FIG. 9 depicts an example usage scenario, in which a portion of a metasurface 932 (with the cut plane 946 depicted) is shown with combined two-part unit cells 990 and 992 positioned proximate a server 994 to cancel noise emanating from the server's fan F. Although not explicitly shown herein, a metasurface or multiple metasurfaces as described herein can be positioned as a noise canceling device proximate a server (FIG. 9) or rack of servers 1094 (FIG. 10), and/or wrapped around at least part of a server or rack of servers 1194 (metasurfaces 1112B, 1112L and 1112R) as depicted in FIG. 11.

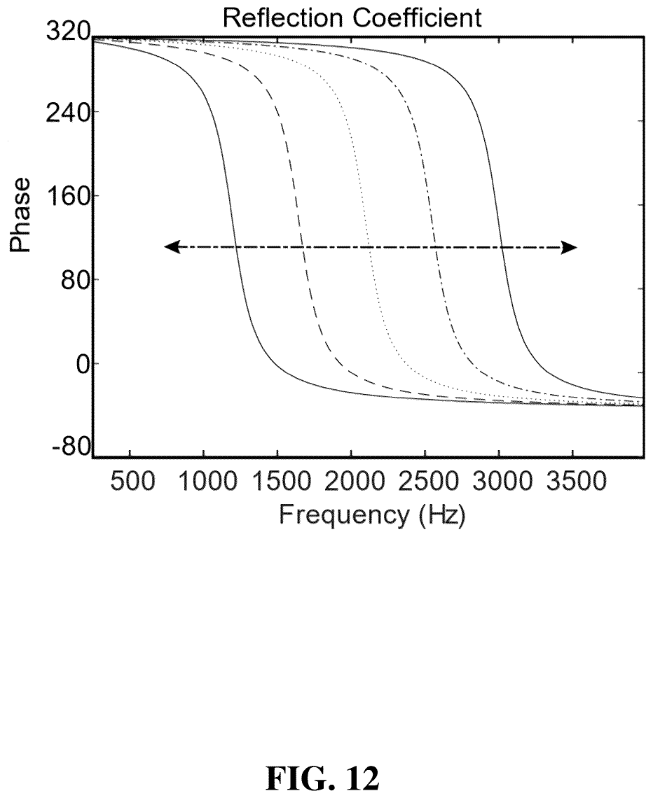

FIG. 12 shows the reflection coefficient resulting from different phases and frequencies. Noise cancellation via the metasurface with adjustable resonant frequency unit cells is thus feasible over a wide range of frequencies.

One or more aspects can be embodied in a system, such as described and represented in the drawing figures herein. The system can include a reconfigurable metasurface configured for sound absorption of an incoming acoustic wave. The reconfigurable metasurface can include a first surface that can include respective first air cavities within a first support, in which the respective first air cavities correspond to respective neck ports of respective first resonator portions; the respective neck ports have respective neck port dimensions. The reconfigurable metasurface further can include a second surface that can include respective second air cavities within a second support, in which the respective second air cavities can correspond to respective chambers of respective second resonator portions; the respective chambers have respective chamber dimensions. The second surface is configured to physically couple to the first surface, with the respective neck ports configured to respectively align with the respective chambers. When the first surface is physically coupled to the second surface, the reconfigurable metasurface can include respective Helmholtz resonators, formed from the respective neck ports and the respective chambers, that resonate at a resonant frequency, based on the respective chamber dimensions and the respective neck port dimensions, to phase cancel the incoming acoustic wave responsive to being exposed to the incoming acoustic wave.

The incoming acoustic wave can be a first incoming acoustic wave, the respective neck ports can be respective first neck ports having respective first neck port dimensions, the respective Helmholtz resonators can be respective first Helmholtz resonators that resonate at a first resonant frequency. The system further can include a third surface that includes respective third air cavities within a third support, in which the respective third air cavities corresponding to respective second neck ports of respective third resonator portions; the respective second neck ports can have respective second neck port dimensions that can be different from the respective first neck port dimensions. When the third surface is physically coupled to the second surface and the first surface is decoupled from the second surface, the reconfigurable metasurface can include respective second Helmholtz resonators, formed from the respective second neck ports and the respective chambers, that resonate at a second resonant frequency, based on the respective chamber dimensions and the respective second neck port dimensions, to phase cancel a second incoming acoustic wave responsive to being exposed to the second incoming acoustic wave.

The respective first neck port dimensions can include respective first widths that can be wider than respective second widths of the respective second neck port dimensions.

The respective first neck port dimensions can include respective first lengths that can be longer than respective second lengths of the respective second neck port dimensions.

At least one of: the respective first neck port dimensions can include respective first widths that can be wider than respective second widths of the respective second neck port dimensions, or the respective first neck port dimensions can include respective first lengths that can be shorter than respective second lengths of the respective second neck port dimensions.

At least one of: the respective first neck port dimensions can include respective first widths that can be narrower than respective second widths of the respective second neck port dimensions, or the respective first neck port dimensions can include respective first lengths that can be longer than respective second lengths of the respective second neck port dimensions.

The incoming acoustic wave can be a first incoming acoustic wave, the respective chambers can be respective first chambers having respective first chamber dimensions, the respective Helmholtz resonators can be respective first Helmholtz resonators that resonate at a first resonant frequency. The system further can include a third surface, that can include respective third air cavities within a third support, in which the respective third air cavities can correspond to respective second chambers of respective third resonator portions; the respective second chambers can have respective second chamber dimensions that can be different from the respective first chamber dimensions. When the third surface is physically coupled to the first surface and the second surface is physically decoupled from the first surface, the reconfigurable metasurface can include respective second Helmholtz resonators, formed from the respective neck ports and the respective second chambers, that resonate at a second resonant frequency, based on the respective second chamber dimensions and the respective neck port dimensions, to phase cancel a second incoming acoustic wave responsive to being exposed to the second incoming acoustic wave.

The respective first chamber dimensions can include respective first widths that can be wider than respective second widths of the respective second chamber dimensions.

The respective first chamber dimensions can include respective first heights that can be longer than respective second heights of the respective second chamber dimensions.

At least one of: the respective first chamber dimensions can include respective first widths that can be wider than respective second widths of the respective second chamber dimensions, or the respective first chamber dimensions can include respective first lengths that can be shorter than respective second lengths of the respective second chamber dimensions.

At least one of: the respective first chamber dimensions can include respective first widths that can be narrower than respective second widths of the respective second chamber dimensions, or the respective first chamber dimensions can include respective first lengths that can be longer than respective second lengths of the respective second chamber dimensions.

One or more aspects can be embodied in a system, such as described and represented in the drawing figures herein. The system can include a cavity sheet panel that can include respective chambers within a supporting cavity sheet structure, a first interchangeable aperture panel that can include respective first neck ports within a first aperture panel supporting structure; and a second interchangeable aperture panel that can include respective second neck ports within a second aperture panel supporting structure. The cavity sheet panel can be configured to be physically coupled to the first interchangeable aperture panel, and can be configured to be coupled to the second interchangeable panel. When the cavity sheet panel is physically coupled to the first interchangeable aperture panel and decoupled from the second interchangeable aperture panel, the respective chambers align with the respective first neck ports to form respective first Helmholtz resonators that resonate at a first resonant frequency that cancels first noise can included by a first incoming acoustic wave comprising a first frequency. When the cavity sheet panel is physically coupled to the second interchangeable aperture panel and decoupled from the first interchangeable aperture panel, the respective chambers align with the respective second neck ports to form respective second Helmholtz resonators that resonate at a second resonant frequency that can be different from the first resonant frequency and that cancels second noise can included by a second incoming acoustic wave comprising a second frequency.

The respective first neck ports can include respective first neck port dimensions having respective first widths that can be wider than respective second widths of the respective second neck port dimensions.

The respective first neck ports can include respective first neck port dimensions having respective first lengths that can be longer than respective second lengths of the respective second neck port dimensions.

The first interchangeable aperture panel can be thicker than the second interchangeable aperture panel.

The respective first neck ports can include respective first neck port dimensions having at least one of: respective first widths that can be wider than respective second widths of the respective second neck port dimensions in conjunction with respective first lengths that can be shorter than respective second lengths of the respective second neck port dimensions, respective first widths that can be narrower than the respective second widths of the respective second neck port dimensions in conjunction with the respective first lengths that can be shorter than the respective second lengths of the respective second neck port dimensions, respective first widths that can be narrower than the respective second widths of the respective second neck port dimensions in conjunction with the respective first lengths that can be longer than the respective second lengths of the respective second neck port dimensions, or respective first widths that can be wider than the respective second widths of the respective second neck port dimensions in conjunction with the respective first lengths that can be longer than the respective second lengths of the respective second neck port dimensions.

One or more aspects can be embodied in a system, such as described and represented in the drawing figures herein. The system can include a cavity sheet panel that includes respective chambers within a supporting cavity sheet part; the cavity sheet panel can be configured to be physically coupled to an interchangeable aperture panel of a group of interchangeable aperture panels. The group of interchangeable aperture panels can include a first interchangeable aperture panel that can include respective first neck ports within a first aperture panel supporting part; the respective first neck ports have respective first neck port dimensions, and a second interchangeable aperture panel that can include respective second neck ports within a second aperture panel supporting part; the respective second neck ports have respective second neck port dimensions. When the cavity sheet panel is physically coupled to the first interchangeable aperture panel and decoupled from the second interchangeable aperture panel, the respective chambers align with the respective first neck ports to form a first metasurface of respective first Helmholtz resonators that resonate at a first resonant frequency, based on the respective first neck port dimensions, that cancels first noise can included by a first incoming acoustic wave. When the cavity sheet panel is physically coupled to the second interchangeable aperture panel and decoupled from the first interchangeable aperture panel, the respective chambers align with the respective second neck ports to form a second metasurface of respective second Helmholtz resonators that resonate at a second resonant frequency, based on the respective second neck port dimensions, that cancels second noise can included by a second incoming acoustic wave.

The respective chambers can be evenly distributed in an array pattern within the supporting cavity sheet part.

The first metasurface can be configured to collectively phase cancel at least one incoming acoustic wave respectively emanating from at least one server.

The respective first neck port dimensions can include respective first widths and respective first lengths, and the respective second neck port dimensions can include respective second widths and respective second lengths. The respective first widths can be wider than the respective second widths and the respective first lengths can be shorter than the respective second lengths. The respective first widths can be narrower than the respective second widths and the respective first lengths can be shorter than the respective second lengths. The respective first widths can be narrower than the respective second widths and the respective first lengths can be longer than the respective second lengths. The respective first widths can be wider than the respective second widths and the respective first lengths can be longer than the respective second lengths. The respective first widths can be wider than the respective second widths and the respective first lengths can be substantially equal to the respective second lengths. The respective first widths can be substantially equal to the respective second widths and the respective first lengths can be shorter than the respective second lengths.

As can be seen, the technology described herein facilitates construction and deployment of a modular/reconfigurable metasurface of unit cells having selectable dimensions, and thus resonant frequencies, determined by coupling one modular interchangeable unit cell portion to another unit cell portion to form a metasurface with unit cells that resonate based on the selected coupled portions' combined dimensions. The metasurface can be implemented in a practical, compact and lightweight surface configuration. As one example, the metasurface is highly useful in the context of mitigating server noise. One unit-cell design achieved high sound absorption of an incoming sound wave at the frequency for which it was designed. Based on the technology described herein, thin, lightweight, and cost effective sound absorbers can be constructed, including by using 3D printing technology.

Among the benefits of the modularity and reconfigurability is to reduce the number of custom surfaces that may be needed, and with noise suppression, to suppress multiple peaks. Static metasurface panels are developed and split, e.g., as part of separate construction, to facilitate a modular approach, using an aperture switching or other switching method. A user can manually switch the target noise suppression frequency using different coupled parts, which can be applied based on categorical information gathered from a compatibility evaluation of noise sources, for example. The noise suppression modules provide the ability to easily switch between different categories of compatible devices, such as different servers.

One implementation uses the neck port cross-sectional area as a variable to reconfigure the resonance frequency of the structure when coupled. The cavity part of the resonator with a larger thickness need not be modified during reconfiguration in this example nonlimiting implementation, as modifying the cross-sectional area of the neck ports among different interchangeable parts that are mechanically switched on top of the cavity part can achieve reconfiguration.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit and scope in accordance with the appended claims.

What is claimed is:

1. A system, comprising:
a reconfigurable metasurface configured for sound absorption of an incoming acoustic wave, the reconfigurable metasurface comprising:
a first surface comprising respective first air cavities within a first support, the respective first air cavities corresponding to respective neck ports of respective first resonator portions, the respective neck ports having respective neck port dimensions; and
a second surface comprising respective second air cavities within a second support, the respective second air cavities corresponding to respective chambers of respective second resonator portions, the respective chambers having respective chamber dimensions, wherein the second surface is configured to physically couple to the first surface, with the respective neck ports configured to respectively align with the respective chambers,
wherein, when the first surface is physically coupled to the second surface, the reconfigurable metasurface comprises respective Helmholtz resonators, formed from the respective neck ports and the respective chambers, that resonate at a resonant frequency, based on the respective chamber dimensions and the respective neck port dimensions, to phase cancel the incoming acoustic wave responsive to being exposed to the incoming acoustic wave.

2. The system of claim 1, wherein the incoming acoustic wave is a first incoming acoustic wave, wherein the respective neck ports are respective first neck ports having respective first neck port dimensions, wherein the respective Helmholtz resonators are respective first Helmholtz resonators that resonate at a first resonant frequency, and further comprising:
a third surface, the third surface comprising respective third air cavities within a third support, the respective third air cavities corresponding to respective second neck ports of respective third resonator portions, the respective second neck ports having respective second neck port dimensions that are different from the respective first neck port dimensions,
wherein, when the third surface is physically coupled to the second surface and the first surface is decoupled from the second surface, the reconfigurable metasurface comprises respective second Helmholtz resonators, formed from the respective second neck ports and the respective chambers, that resonate at a second resonant frequency, based on the respective chamber dimensions and the respective second neck port dimensions, to phase cancel a second incoming acoustic wave responsive to being exposed to the second incoming acoustic wave.

3. The system of claim 2, wherein the respective first neck port dimensions comprise respective first widths that are wider than respective second widths of the respective second neck port dimensions.

4. The system of claim 2, wherein the respective first neck port dimensions comprise respective first lengths that are longer than respective second lengths of the respective second neck port dimensions.

5. The system of claim 2, wherein at least one of: the respective first neck port dimensions comprise respective first widths that are wider than respective second widths of the respective second neck port dimensions, or the respective first neck port dimensions comprise respective first lengths that are shorter than respective second lengths of the respective second neck port dimensions.

6. The system of claim 2, wherein at least one of: the respective first neck port dimensions comprise respective first widths that are narrower than respective second widths of the respective second neck port dimensions, or the respective first neck port dimensions comprise respective first lengths that are longer than respective second lengths of the respective second neck port dimensions.

7. The system of claim 1, wherein the incoming acoustic wave is a first incoming acoustic wave, wherein the respective chambers are respective first chambers having respective first chamber dimensions, wherein the respective Helmholtz resonators are respective first Helmholtz resonators that resonate at a first resonant frequency, and further comprising:
a third surface, the third surface comprising respective third air cavities within a third support, the respective third air cavities corresponding to respective second chambers of respective third resonator portions, the respective second chambers having respective second chamber dimensions that are different from the respective first chamber dimensions,
wherein, when the third surface is physically coupled to the first surface and the second surface is physically decoupled from the first surface, the reconfigurable metasurface comprises respective second Helmholtz resonators, formed from the respective neck ports and the respective second chambers, that resonate at a second resonant frequency, based on the respective second chamber dimensions and the respective neck port dimensions, to phase cancel a second incoming acoustic wave responsive to being exposed to the second incoming acoustic wave.

8. The system of claim 7, wherein the respective first chamber dimensions comprise respective first widths that are wider than respective second widths of the respective second chamber dimensions.

9. The system of claim 7, wherein the respective first chamber dimensions comprise respective first heights that are longer than respective second heights of the respective second chamber dimensions.

10. The system of claim 7, wherein at least one of: the respective first chamber dimensions comprise respective first widths that are wider than respective second widths of the respective second chamber dimensions, or the respective first chamber dimensions comprise respective first lengths that are shorter than respective second lengths of the respective second chamber dimensions.

11. The system of claim 7, wherein at least one of: the respective first chamber dimensions comprise respective first widths that are narrower than respective second widths of the respective second chamber dimensions, or the respective first chamber dimensions comprise respective first lengths that are longer than respective second lengths of the respective second chamber dimensions.

12. A system, comprising:
a cavity sheet panel comprising respective chambers within a supporting cavity sheet structure;
a first interchangeable aperture panel comprising respective first neck ports within a first aperture panel supporting structure; and
a second interchangeable aperture panel comprising respective second neck ports within a second aperture panel supporting structure,
wherein the cavity sheet panel is configured to be physically coupled to the first interchangeable aperture panel, and is configured to be coupled to the second interchangeable panel, and wherein:
when the cavity sheet panel is physically coupled to the first interchangeable aperture panel and decoupled from the second interchangeable aperture panel, the respective chambers align with the respective first neck ports to form respective first Helmholtz resonators that resonate at a first resonant frequency that cancels first noise comprised by a first incoming acoustic wave comprising a first frequency, and
when the cavity sheet panel is physically coupled to the second interchangeable aperture panel and decoupled from the first interchangeable aperture panel, the respective chambers align with the respective second neck ports to form respective second Helmholtz resonators that resonate at a second resonant frequency that is different from the first resonant frequency and that cancels second noise comprised by a second incoming acoustic wave comprising a second frequency.

13. The system of claim 12, wherein the respective first neck ports comprise respective first neck port dimensions having respective first widths that are wider than respective second widths of the respective second neck port dimensions.

14. The system of claim 12, wherein the respective first neck ports comprise respective first neck port dimensions having respective first lengths that are longer than respective second lengths of the respective second neck port dimensions.

15. The system of claim 12, wherein the first interchangeable aperture panel is thicker than the second interchangeable aperture panel.

16. The system of claim 12, wherein the respective first neck ports comprise respective first neck port dimensions having at least one of:
respective first widths that are wider than respective second widths of the respective second neck port dimensions in conjunction with respective first lengths that are shorter than respective second lengths of the respective second neck port dimensions,
the respective first widths that are narrower than the respective second widths of the respective second neck port dimensions in conjunction with the respective first lengths that are shorter than the respective second lengths of the respective second neck port dimensions,
the respective first widths that are narrower than the respective second widths of the respective second neck port dimensions in conjunction with the respective first lengths that are longer than the respective second lengths of the respective second neck port dimensions, or
the respective first widths that are wider than the respective second widths of the respective second neck port dimensions in conjunction with the respective first lengths that are longer than the respective second lengths of the respective second neck port dimensions.

17. A system, comprising:
a cavity sheet panel comprising respective chambers within a supporting cavity sheet part, wherein the cavity sheet panel is configured to be physically coupled to an interchangeable aperture panel of a group of interchangeable aperture panels, the group of interchangeable aperture panels comprising:
a first interchangeable aperture panel comprising respective first neck ports within a first aperture panel supporting part, wherein the respective first neck ports have respective first neck port dimensions; and
a second interchangeable aperture panel comprising respective second neck ports within a second aperture panel supporting part, wherein the respective second neck ports have respective second neck port dimensions,
wherein, when the cavity sheet panel is physically coupled to the first interchangeable aperture panel and decoupled from the second interchangeable aperture panel, the respective chambers align with the respective first neck ports to form a first metasurface of respective first Helmholtz resonators that resonate at a first resonant frequency, based on the respective first neck port dimensions, that cancels first noise comprised by a first incoming acoustic wave, and
wherein, when the cavity sheet panel is physically coupled to the second interchangeable aperture panel and decoupled from the first interchangeable aperture panel, the respective chambers align with the respective second neck ports to form a second metasurface of respective second Helmholtz resonators that resonate at a second resonant frequency, based on the respective second neck port dimensions, that cancels second noise comprised by a second incoming acoustic wave.

18. The system of claim 17, wherein the respective chambers are evenly distributed in an array pattern within the supporting cavity sheet part.

19. The system of claim 17, wherein the first metasurface is configured to collectively phase cancel at least one incoming acoustic wave respectively emanating from at least one server.

20. The system of claim 17, wherein the respective first neck port dimensions comprise respective first widths and respective first lengths, wherein the respective second neck port dimensions comprise respective second widths and respective second lengths, and wherein:
the respective first widths are wider than the respective second widths and the respective first lengths are shorter than the respective second lengths,
the respective first widths are narrower than the respective second widths and the respective first lengths are shorter than the respective second lengths,
the respective first widths are narrower than the respective second widths and the respective first lengths are longer than the respective second lengths,
the respective first widths are wider than the respective second widths and the respective first lengths are longer than the respective second lengths,
the respective first widths are wider than the respective second widths and the respective first lengths are substantially equal to the respective second lengths, or
the respective first widths are substantially equal to the respective second widths and the respective first lengths are shorter than the respective second lengths.
